(19) United States
(12) Patent Application Publication
(10) Pub. No.: US 2007/0013561 A1
(43) Pub. Date: Jan. 18, 2007

(54) Signal coding

(76) Inventors: Qian Xu, College Station, TX (US); Zixiang Xiong, Spring, TX (US)

Correspondence Address: BERKELEY LAW & TECHNOLOGY GROUP, 1700NW 167TH PLACE, SUITE 240, BEAVERTON, OR, 97006, US

(21) Appl. No.: 11/336,637

(22) Filed: Jan. 20, 2006

Related U.S. Application Data
(60) Provisional application No. 60/645,712, filed on Jan. 20, 2005.

(51) Int. Cl. H03M 7/00

(52) U.S. Cl. 341/50

(57) ABSTRACT

Embodiments of techniques for signal coding are disclosed

### RELATED APPLICATION

This patent application claims priority to U.S. provisional patent application Ser. No. 60/645,712, titled “SIGNAL CODING,” filed on Jan. 20, 2005, by Xu et al., assigned to the assignee of the presently claimed subject matter.

### FIELD

This disclosure is related to signal coding and, more particular, to techniques for signal compression.

### BACKGROUND

Signal compression continues to be desirable for a variety of situations and, therefore, techniques for accomplishing signal compression continue to be sought.

### BRIEF DESCRIPTION OF THE DRAWINGS

Subject matter is particularly pointed out and distinctly claimed in the concluding portion of the specification. Claimed subject matter, however, both as to organization and method of operation, together with objects, features, and advantages thereof, may best be understood by reference of the following detailed description if read with the accompanying drawings in which:

FIG. 1 is a block diagram of a portion of an embodiment;

FIG. 2 is a diagram to illustrate an embodiment of NSQ;

FIG. 3 is a diagram to illustrate an embodiment including two-stages of a decoder;

FIG. 4 is a plot of a probability density function; and

FIG. 5 is a block diagram of another portion of an embodiment.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail so as not to obscure claimed subject matter.

Some portions of the detailed description which follow are presented in terms of algorithms and/or symbolic representations of operations on data bits or binary digital signals stored within a computing system, such as within a computer or computing system memory. These algorithmic descriptions and/or representations are the techniques used by those of ordinary skill in the data processing arts to convey the substance of their work to others skilled in the art. An algorithm is here, and generally, considered to be a self-consistent sequence of operations and/or similar processing leading to a desired result. The operations and/or processing involve physical manipulations of physical quantities. Typically, although not necessarily, these quantities may take the form of electrical and/or magnetic signals capable of being stored, transferred, combined, compared and/or otherwise manipulated. It has proven convenient, at times, principally for reasons of common usage, to refer to these signals as bits, data, values, elements, symbols, characters, terms, numbers, numerals and/or the like. It should be understood, however, that all of these and similar terms are to be associated with the appropriate physical quantities and are merely convenient labels. Unless specifically stated otherwise, as apparent from the following discussion, it is appreciated that throughout this specification discussions utilizing terms such as “processing”, “computing”, “calculating”, “determining” and/or the like refer to the actions and/or processes of a computing platform, such as a computer or a similar electronic computing device, that manipulates and/or transforms data represented as physical electronic and/or magnetic quantities and/or other physical quantities within the computing platform's processors, memories, registers, and/or other information storage, transmission, and/or display devices.

In this context, Wyner-Ziv coding refers to lossy source coding with side information at the decoder. Recently, some practical applications of Wyner-Ziv coding to video compression have been studied. For one embodiment of signal coding, a practical layered Wyner-Ziv video codec comprises using the discrete cosine transform (DCT), nested scalar quantizer (NSQ), and irregular low density parity coding (LDPC) code based Slepian-Wolf coding, although, of course, claimed subject matter is not limited in scope in this respect. The DCT is applied as an approximation to the conditional Karhunen-Loeve transform (KLT), so that components of the transformed block are conditionally independent given side information. NSQ comprises a binning scheme that facilitates layered bit-plane coding of bin indices while reducing the bit rate. LDPC code based Slepian-Wolf coding exploits correlation between the quantized version of the source and side information to achieve further compression, as described in more detail hereinafter. In one embodiment, decoding is allowed at lower bit rates without significant quality loss, although claimed subject matter is not limited in scope to such an embodiment.

The growing popularity of real-time and on-demand streaming of video over noisy channels has prompted a desire for scalable and/or robust video coding, although, claimed subject matter is not limited in scope to streaming video. Conventional video coding standards, such as MPEG-4 and H.26L, for example, typically perform well under noiseless channel conditions. But they may perform less well in the presence of losses or errors over time-varying error-prone channels. As previously indicated, Wyner-Ziv coding refers to lossy compression with side information at the decoder. An example of the Wyner-Ziv coding approach provides a source X and side information Y as zero mean and stationary Gaussian memoryless sources and a distortion metric as MSE. A bit rate to encode X for a given distortion if Y is available at the decoder is the rate if Y is known at both sides. In other words, little or no rate loss for a quadratic Gaussian case occurs in Wyner-Ziv (WZ) coding. Using this result, embodiments disclosed herein include standard closed-loop differential pulse code modulation (DPCM)-based video encoders modified into an open-loop codec to address error drifting for noisy channels.

In one embodiment of a signal coder, a layered video coding scheme is based at least in part on successive refinement using a WZ coding approach, which indicates that a quadratic Gaussian source is successively refinable. Treating a standard coded video as a base layer (or side information), a layered Wyner-Ziv bitstream of an original video sequence may be generated to enhance the base layer such that it is decodable with commensurate qualities at rates corresponding to layer boundaries.

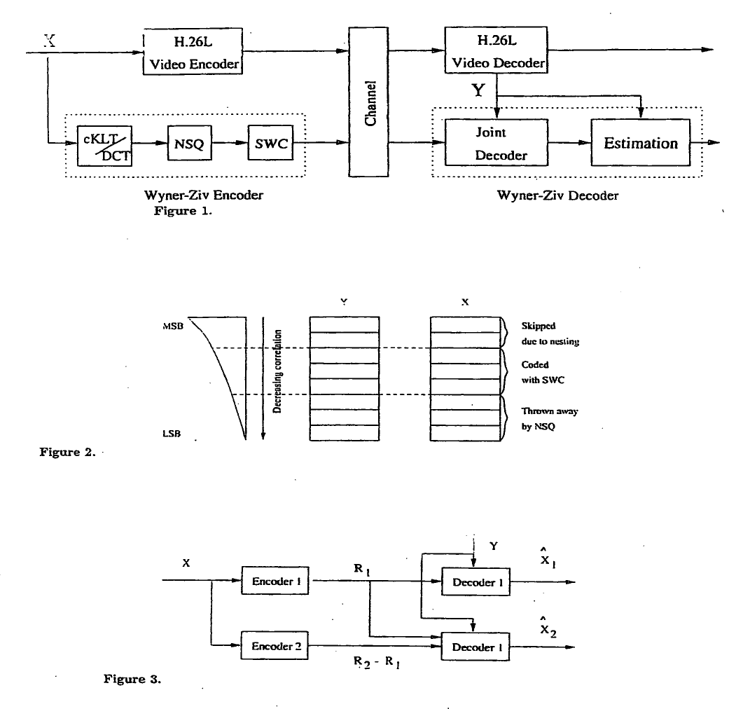

FIG. 1 depicts a block diagram of an embodiment of a layered Wyner-Ziv codec. Here, such an encoder includes three components: the DCT, nested scalar quantization (NSQ) and Slepian-Wolf coding (SWC) based on irregular LDPC codes.

In the first component, the DCT approximates a conditional KLT so that coefficients of a transformed block of the original video X are conditionally independent given the same transformed block of side information Y. NSQ comprises a binning process that partitions input DCT coefficients into cosets and outputs coset indices. For this embodiment, upper bit planes of DCT coefficients are skipped in NSQ due at least in part to high correlation to those in the side information. There will be loss in video quality with this binning process if side information is not used to recover these upper bit planes in the joint Wyner-Ziv decoder. Lower bit planes are less significant and, hence, quantized to zero by NSQ. Therefore, both upper and lower bit planes are thrown away in NSQ and those in between are coded, as illustrated in FIG. 2. NSQ introduces both binning loss, which may be kept relatively small with strong coset/channel coding, and quantization loss, that may be traded off with rate in source coding. In addition, there is correlation between a quantized version (bit planes in the middle) of the source X and side information Y and SWC may thus be employed to exploit this correlation by sending syndromes to achieve further compression, in this particular embodiment. This embodiment employs multi-level LDPC codes for SWC (or lossless source coding of the quantized source with side information at the decoder) in the third component of the encoder and outputs one layer of compressed bitstream for a bit plane after NSQ, although other embodiments are possible. In doing so, correlation decreases from the most significant bit (MSB) to the least significant bit (LSB). Thus, for this embodiment, higher rates may be assigned to higher bit planes (with higher rate LDPC codes) for more compression; with lower rates given to lower bit planes for less compression. Furthermore, for this particular embodiment, to facilitate layered coding, the order of encoding proceeds from the MSB to the LSB after NSQ, although claimed subject matter is not limited in scope in this respect.

At the decoder, for this embodiment, additional bitstream/syndrome layers may be combined with previously decoded bit planes to decode a new bit plane before joint estimation of the output video, although, again, claimed subject matter is not limited in this result. However, this multi-level decoding scheme permits progressive decoding with additional layers improving upon the decoded video quality. Progressive decoding is desirable in a variety of situations. For example, a coarse description of a source may suffice at a first stage with low bit rate, and fine details may be desired at some later stage with higher bit rate. Thus, this particular coding scheme embodiment is similar to MPEG-4/H.26L FGS coding in terms of having an embedded enhancement layer with good rate-distortion (R-D) performance. However, a difference here is that an enhancement layer is generated “blindly” without knowledge about the base layer. This at least reduces error drifting/propogation associated with encoder-decoder mismatch in standard DPCM-based coders. In this embodiment, encoding that takes place once thereby permits decoding at lower bit rates with commensurate qualities. While this particular code design embodiment assumes ideal Gaussian sources, results described hereinafter illustrate embodiments of practical coding of video that do not appear to suffer significant performance loss due to layering.

The problem of successive refinement of information was previously formulated by Equitz and Cover. A source X is to be encoded and transmitted through a rate-limited channel. With rate R₁, the decoder produces X₁′, which is an approximation of X as distortion level D₁. At a later stage, the encoder sends a secondary string at rate ΔR to the decoder. With both bitstreams at hand, the decoder will produce X₂′, a more accurate reconstruction of X at distortion level D₂. If successive coding in two or more stages can be improved at all stages, the source is called successively refinable. For the two-stage case, the two rates should lie on the R-D curve, i.e.,
R₁=R_{X}(D₁) and R₁+ΔR=R_{X}(D₂) (1)
where RX(D) is the R-D function of the source X at distortion level D. It has been shown that a condition for a source to be successively refinable is that the conditional distributions f(X₁′/X) and f(X₂′/X) are Markov compatible in the sense that they can be represented as a Markov chain X→X₂′→X₁′.

A successive refinement code for WV coding comprises multi-stage encoders and decoders in which a decoder uses the information generated from decoders of its earlier stages. FIG. 3 depicts an embodiment of two-stage successive coding for WV with the side information at each stage being the same.

Let Y be side information available to the decoder at both the coarse and the refinement stages, and the corresponding coding rates (distortions) are R₁(D₁) and R₂(D₂), respectively. Let R′_{x/y}(D) be the Wyner-Ziv R-D function. According to (1), a source X is said to be successively refinable from D₁ to D₂ (D₁>D₂) with side information Y if
R₁=R′_{x/y}(D₁) and R₁+ΔR=R′_{x/y}(D₂) (2)

Of course, for alternate embodiments, the notion of successive coding can be extended to any finite number of stages. Consider the case if side information fed into K decoders at each level is substantially the same. Source X is multi-stage successively refinable with side information Y if
R₁=R′_{x/y}(D₁) and Rᵢ+ΔRᵢ=R′_{x/y}(Dᵢ₊₁); for i=1; 2; : : : k−1 (3)
A jointly Gaussian source (with MSE measure) may be shown to be multi-stage successively refinable in the Wyner-Ziv setting.

Layered Wyner-Ziv code design embodiments have been described above for ideal Gaussian sources. This embodiment now comprises a practical layered Wyner-Ziv code design embodiment for real video sources based at least in part on NSQ and multi-level LDPC code for Slepian-Wolf coding. We denote a current frame of an original video as x and an H.26L decoded version of x as y. For Wyner-Ziv coding of x, we first apply the cKLT (approximated by the DCT) to every 4×4 block of x so that components of the transformed block X=Tx (T is related to both x and y) are conditionally independent given the side information y, which is also transformed into Y=Ty. DCT coefficients that are statistically similar in terms of variance are group together in the SWC operation. Frequency components of Y (denoted by Y) act as side information for the corresponding component of X (denoted by X). We assume that X and Y are jointly Gaussian with Y=X+Z, where Z is zero-mean Gaussian and independent of X (although DCT coefficients of images/video may also be modeled as Laplacian distributed).

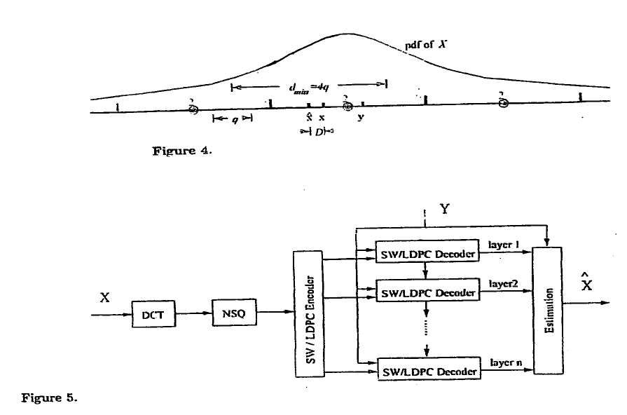

Next is NSQ, which, for this particular embodiment, comprises a coarse coset channel code nested in a fine uniform scalar quantizer. FIG. 4 shows a simple 1-D nested uniform quantizer with N=4 cosets, in which the fine source code employs a uniform scalar quantizer with stepsize q and the coarse channel code with minimum distance dₘᵢₙ=Nq. To encode, X is first quantized by the fine source code (uniform quantizer), resulting in an average quantization error of D_{SC}=q²/12 at high rate. However, index B (0<=B<=N-1) of the coset in the coarse channel code that the quantized X belongs to is coded to save rate. Using the coded coset index B, the decoder finds in the coset a codeword closest to side information Y as an estimate of X. Due at least in part to the coset channel code employed in a nesting process, the Wyner-Ziv decoder suffers a small probability of error that is inversely proportional to dₘᵢₙ=Nq. It is desirable to choose a small quantization stepsize q to reduce distortion D_{SC} associated with source coding. On the other hand, dₘᵢₙ should be increased to reduce distortion D_{CC} associated with channel decoding. Thus, for a fixed N, there exists a q to reduce total distortion D=D_{SC}+D_{CC}.

Due to correlation between X and Y, there still remains correlation between the quantized version B of X and side information Y. Ideal SWC may be used to compress B to the rate of R=H(B/Y). Suppose one expresses B in its binary representation as B=B0B1 . . . Bn, where B0 is the MSB and Bn is the LSB. In this embodiment, employ multi-level LDPC codes to compress B0B1 . . . Bn using the syndrome approach. The rate of the LDPC code for Bᵢ (0<=|<=n) depends at least in part on the conditional entropy H(Bi/Y;Bi-1 . . . B0), which denotes the rate to losslessly recover Bi given Y and Bi-1 . . . B0 at the decoder.

In simulations for this particular embodiment, we have assumed ideal SWC in the sense that the rate R=H(B/Y) can be achieved. For each fixed N (number of cosets in the channel code), we vary the uniform quantization step size q to generate a set of R-D points (R,D) and pick the q′ corresponding to the point with the steepest R-D slope from the zero-rate point in Wyner-Ziv coding. Note that the distortion for the zero-rate point is ∥X-Y∥², which is the average distortion of base layer coding due to H.26L. After identifying the R-D points for different N, the lower convex hull of these points form the operational R-D curve of Wyner-Ziv coding. Quadratic Gaussian sources are successively refinable; therefore, the same operational R-D curve may be traversed for this embodiment by starting with a large N (with its corresponding q′) and sequentially dropping bit planes of B. In other words, by setting different low bit plane levels of B to zero, the resulting R-D points after Wyner-Ziv decoding may lie on the operational R-D curve. Simulations for these embodiments verify this property of successive refinement and indicate some desirability for the practice of coding Bi into the i-th layer with rate H(Bi/Y;Bi-1 . . . B0), as illustrated by the embodiment shown in FIG. 5, although claimed subject matter is not limited in scope in this respect. By the chain rule H(B/Y)=H(B0/Y)+H(B1/B0; Y)+ : : : +H(Bn/B0 . . . Bn-1; Y). So layered coding suffers little or no rate loss if compared with monolithic coding.

In this practical irregular LDPC code design embodiment, the code degree distribution polynomials λ(x) and ρ(x) of the LDPC codes are improved using density evolution with a Gaussian approximation. A bipartite graph (an equivalent representation of the parity-check matrix H) for an irregular LDPC code is randomly constructed based at least in part on code degree polynomials λ(x) and ρ(x). To compress bit plane Bi, corresponding syndromes determined at least in part by the sparse parity check matrix of the irregular LDPC code are coded. At the decoder, received syndrome bits for the layers (or bit plane) may be combined with tdecoded bits of previous bit planes and side information Y to perform joint decoding. Let Bi′ represent the reconstruction of Bi. A message-passing process, see “Analysis of sum-product decoding of low-density parity check codes using a Gaussian approximation,” by Chung et al, IEEE Trans. Inform. Theory, Vol. 47, pp 657-670, February 2001, may be used for iterative LDPC decoding, in which received syndrome bits correspond to check nodes on a bipartite graph, side information and previously decoded bit planes provide a priori information as to the probability that the current bit is “1” or “0”, i.e.,
LLR=p(Bi=0/Y, B0′, . . . Bi-1)/p(Bi=1/Y, B0′, . . . Bi-1) (4)

After decoding B0 as B0′, both B0′ and Y may be fed into the decoder for decoding of B1. Since the allocated bit rate for coding B1 is H(B1/Y;B0), B1 can be decoded as long as B0′=B0. By multi-stage decoding, Bi can be recovered with the help of Y and previously decoded bit planes B0B1 . . . Bi-1, which are available at the decoder. The more syndrome layers the decoder receives or the higher the bit rate, the more bit planes of B will be recovered to better reconstruct X. Therefore, successive Wyner-Ziv coding provides the flexibility to accommodate a wide range of bit rates.

Theoretically, there is no rate difference between the order of bit plane coding. Therefore, coding from the MSB to the LSB is substantially the same as coding from the LSB to the MSB. However, in practice, for this particular embodiment, we code from the MSB to the LSB in this layered scheme, although claimed subject matter is not limited in scope in this respect.

For this embodiment, we perform estimation at the joint decoder. The decoded coset index B0′ B1′ . . . Bi′ specifies the uncertainty region of X. Side information essentially supplies a conditional PDF of X given Y, which is that of a Gaussian with mean Y and variance proportional to the correlation between Y and X. AN estimate of X is computed as a conditional centroid ‘X=E(X/B0 ‘B1’ : : : Bi′; Y). The inverse DCT is applied to X′ to obtain x′ in the pixel domain. An embodiment of claimed subject matter may includes a practical layered video coder based at least in part on the Wyner-Ziv coding principle. One implementation may be based at least in part on H.26L, although claimed subject matter is not limited in scope in this respect.

It will, of course, be understood that, although particular embodiments have just been described, claimed subject matter is not limited in scope to a particular embodiment or implementation. For example, one embodiment may be in hardware, such as implemented to operate on a device or combination of devices, for example, whereas another embodiment may be in software. Likewise, an embodiment may be implemented in firmware, or as any combination of hardware, software, and/or firmware, for example. Likewise, although claimed subject matter is not limited in scope in this respect, one embodiment may comprise one or more articles, such as a storage medium or storage media. This storage media, such as, one or more CD-ROMs and/or disks, for example, may have stored thereon instructions, that if executed by a system, such as a computer system, computing platform, or other system, for example, may result in an embodiment of a method in accordance with claimed subject matter being executed, such as one of the embodiments previously described, for example. As one potential example, a computing platform may include one or more processing units or processors, one or more input/output devices, such as a display, a keyboard and/or a mouse, and/or one or more memories, such as static random access memory, dynamic random access memory, flash memory, and/or a hard drive. For example, a display may be employed to display one or more queries, such as those that may be interrelated, and or one or more tree expressions, although, again, claimed subject matter is not limited in scope to this example.

In the preceding description, various aspects of claimed subject matter have been described. For purposes of explanation, specific numbers, systems and/or configurations were set forth to provide a thorough understanding of claimed subject matter. However, it should be apparent to one skilled in the art having the benefit of this disclosure that claimed subject matter may be practiced without the specific details. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all such modifications and/or changes as fall within the true spirit of claimed subject matter.

1. A method of signal compression comprising:
applying irregular LDPC code based Slepiam-Wolf coding to a set of signals.

2. The method of claim 1, wherein said set of signals comprises at least one of: data; video; imaging; and/or audio signals.

3. The method of claim 1, and further comprising, prior to said applying, quantizing said set of signals.

4. The method of claim 3, wherein said quantizing comprises nested scalar quantizing.

5. The method of claim 4, wherein said coding is applied from a most significant bit to a least significant bit of said set of signals.

6. A method of signal decompression comprising:
receiving a compressed bit stream; said compressed bit stream being generated by applying irregular LDPC code based Slepiam-Wolf coding; and
combining said received bit stream with previously decoded bit planes to decode a new bit plane.

7. The method of claim 6, and further comprising: jointly estimating the received signals.

8. The method of claim 7, wherein the estimated received signals comprise at least one of: data; video; imaging; and/or audio signals.

9. The method of claim 6, wherein receiving a compressed bit stream comprises receiving layered compressed bit streams.

10. An apparatus comprising:
a nested scalar quantizer, and an irregular-LDPC-code-based Slepian-Wolf coder coupled so as to form a codec.

11. The apparatus of claim 10, wherein said codec is incorporated into a computing platform.

12. An article comprising: a storage medium having stored thereon instructions that if executed result in:
applying irregular LDPC code based Slepiam-Wolf coding to a set of signals.

13. The article of claim 12, wherein said instructions if executed further result in quantizing said set of signals prior to the coding.

14. A method comprising: a step (a) of using a lossless source coding with side-information for encoding a data segment.

15. The method of claim 14, further comprising a step (b) of decoding the data segment at a plurality of bit rates that are each lower than an original bit rate of the data segment.

16. The method of claim 14, in which the using step (a) includes a step (a1) of encoding the data segment using a nested scalar quantizer, and in which the encoding step (a1) includes steps of:
(a1A) dividing the data segment into at least upper, intermediate, and lower bit planes; and
(a1B) encoding the intermediate bit planes without encoding the upper and lower bit planes.

17. The method of claim 14, further comprising a step (b) of decoding, in which the decoding step (b) includes steps of:
(b1) combining several syndrome layers to decode a new bit plane; and
(b2) estimating an output based at least in part on the new bit plane.

18. The method of claim 14 in which the using step (a) includes a step of encoding the data segment as a video segment of at least 100 frames with an original frame rate of 30 Hertz.

19. A network comprising:
a codec including a DCT, a nested scalar quantizer, and an irregular-LDPC-code-based Slepian-Wolf coder; and
a spatially distributed network of several sensors and several signal paths, the network configured to transmit information from each of the sensors to the codec.
